(19) United States
(12) Patent Application Publication
(10) Pub. No.: US 2025/0131143 A1
(43) Pub. Date: Apr. 24, 2025

(54) DURABILITY EVALUATION METHOD FOR TUNING MODEL PARAMETER AND DURABILITY EVALUATION SYSTEM USING THE SAME

(71) Applicants: HYUNDAI MOTOR COMPANY, SEOUL (KR); KIA CORPORATION, SEOUL (KR)

(72) Inventors: You Jin SHIN, Seoul (KR); Se Do OH, Seoul (KR)

(21) Appl. No.: 18/825,778

(22) Filed: Sep. 5, 2024

(30) Foreign Application Priority Data
Oct. 20, 2023 (KR) 10-2023-0140975

(51) Int. Cl. G06F 30/15

(52) U.S. Cl. CPC G06F 30/15

(57) ABSTRACT

A durability evaluation method performed by a processor including filtering, by a data filter, a first data set for each of a plurality of meshes of a target vehicle and a second data set with an adjusted material or thickness of the target vehicle to output data, determining, by a binary classifier, the first synthetic data for indicating durability performance less than a predetermined threshold value from feature data from the filtered data and the first synthetic data, generating, by a probability inferring unit, second output data for representing the probability belonging to each of a predetermined number of durability probability sections, from the durability performance of the first output data and the second synthetic data, and determining a plurality of hyperparameter values constituting each of the data filter, the binary classifier, and the probability inferring unit.

### CROSS-REFERENCE TO RELATED APPLICATION

This application claims priority to and the benefit of Korean Patent Application No. 10-2023-0140975 filed in the Korean Intellectual Property Office on Oct. 20, 2023, the entire contents of which are incorporated herein by reference.

### BACKGROUND

### (a) Field

The present disclosure relates to a durability evaluation method for tuning a model parameter and a durability evaluation system using the same.

### (b) Description of the Related Art

Durability performance of a vehicle is a concept that includes functional performance of a vehicle to withstand external shock, load, environment, or the like. The durability performance of the vehicle is directly related to the safety of passengers in the vehicle, and therefore, is managed as an important performance indicator during the development stage of the vehicle.

The Belgian durability test results may be used as one of the methods for evaluating durability performance of a vehicle. The Belgian durability test is a test that evaluates durability performance of a vehicle by driving a vehicle on a Belgian road that makes driving of a vehicle harsh and extracting data for durability performance.

The Belgian durability test may also be conducted in a virtual environment. However, such simulations to extract data for a durability performance by performing the Belgian durability test in a virtual environment may take a lot of time.

### SUMMARY

The present disclosure provides a method and system for evaluating durability performance of a vehicle based on three-dimensional (3D) data for the vehicle, determining whether the durability performance of the vehicle satisfies predetermined criteria, determining a probability distribution for an indicator value indicating the durability performance of the vehicle, and optimizing a model by tuning a model parameter using an objective function.

According to an aspect of the present disclosure, a durability evaluation method performed by a processor includes filtering, by a data filter, a first data set for each of a plurality of meshes constituting a body of a target vehicle and a second data set for each of a plurality of meshes constituting a body of a virtual vehicle with an adjusted material or thickness of the target vehicle to output data indicating durability performance that is less than a predetermined filter criterion, extracting feature data from the data indicating the durability performance that is less than the predetermined filter criterion, generating first synthetic data in which the durability performance is less than a predetermined threshold value, and determining data for a mesh indicating durability performance less than a predetermined threshold value among the plurality of meshes as first output data from the feature data and the first synthetic data through a binary classifier, generating second synthetic data indicating durability performance belonging to a predetermined number of durability probability sections based on the first output data, and determining data indicating a probability that the durability probability belongs to each of the predetermined number of durability probability sections from the first output data and the second synthetic data as second output data through a probability inferring unit, and determining a plurality of hyperparameter values constituting each of the data filter, the binary classifier, and the probability inferring unit so that a misclassification rate of each of the data filter, the binary classifier, and the probability inferring unit is reduced.

The determining of the plurality of hyperparameter values may include setting first hyperparameters corresponding to the data filter, second hyperparameters corresponding to the binary classifier, and third hyperparameters corresponding to each of the probability inferring units, setting objective functions of each of the data filter, the binary classifier, and the probability inferring unit to determine values of the first to third hyperparameters, and determining values of corresponding hyperparameters among the first to third hyperparameters so that the objective function value is minimized.

The setting of the objective functions of each of the data filter, the binary classifier, and the probability inferring unit may include setting a first objective function of the data filter by adding a value obtained by multiplying a False-Positive rate of data predicted by the data filter by a predetermined adjustment coefficient and a False-Negative rate, and the determining of the values of the corresponding hyperparameters among the first to third hyperparameters may include determining values of each of the first hyperparameters so that the first objective function value is minimized.

The setting of the objective functions of each of the data filter, the binary classifier, and the probability inferring unit may include setting a second objective function of the binary classifier by adding indicators indicating that the misclassification data is correctly predicted data within a predetermined range based on the misclassification rate of the data predicted by the binary classifier and the misclassification data of the binary classifier, and the determining of the values of the corresponding hyperparameters among the first to third hyperparameters may include determining values of each of the second hyperparameters so that the second objective function value is minimized.

The setting of the objective functions of each of the data filter, the binary classifier, and the probability inferring unit may include setting a third objective function of the probability inferring unit by adding, by the probability inferring unit, a difference between accuracy of the predicted data and a reference value of the accuracy for each of the predetermined number of durability probability sections and a predetermined multiple of a standard deviation between accuracies in the predetermined number of durability probability sections, and the determining of the values of the corresponding hyperparameters among the first to third hyperparameters may include determining values of each of the third hyperparameters so that the third objective function value is minimized.

The durability evaluation method may further include sampling nearby data based on the values of each of the hyperparameters, determining a surrogate indicating the sampled data, and optimizing the values of the corresponding hyperparameters among the first to third hyperparameters by updating interpolation and scaling of the value using the surrogate.

According to another aspect of the present disclosure, a durability evaluation system includes a collection unit that collects, by a data filter, a first data set for each of a plurality of meshes constituting a body of a target vehicle and a second data set for each of a plurality of meshes constituting a body of a virtual vehicle with an adjusted material or thickness of the target vehicle, and a processor that outputs data indicating a probability that durability performance belongs to each of a predetermined number of durability probability sections from the first data set and the second data set, in which the processor includes the data filter that outputs filter data indicating durability performance that is less than a predetermined filter criterion from the first data set and the second data set, a binary classifier that determines, as first output data, data for a mesh indicating the durability performance less than a predetermined threshold value among the plurality of meshes from feature data extracted from the filter data and first synthetic data in which the durability performance synthesized from the feature data is less than the predetermined threshold value, a probability inferring unit that determines, as second output data, data indicating a probability that the durability performance belongs to each of the predetermined number of durability probability sections from the first output data and second synthetic data indicating the durability performance belonging to the predetermined number of durability probability sections synthesized based on the first output data, and a model tuner that determines a plurality of hyperparameter values constituting each of the data filter, the binary classifier, and the probability inferring unit so that a misclassification rate of each of the data filter, the binary classifier, and the probability inferring unit is reduced.

The model tuner may include an objective function setting unit that sets first hyperparameters corresponding to the data filter, second hyperparameters corresponding to the binary classifier, and third hyperparameters corresponding to each of the probability inferring units and sets objective functions of each of the data filter, the binary classifier, and the probability inferring unit for determining values of the first to third hyperparameters, and a parameter value determination unit that determines values of corresponding hyperparameters among the first to third hyperparameters so that the objective function value is minimized.

The objective function setting unit may set a first objective function of the data filter by adding a value obtained by multiplying a False-Positive rate of data predicted by the data filter by a predetermined adjustment coefficient and a False-Negative rate, and the parameter value determination unit may determine values of each of the first hyperparameters so that the first objective function value is minimized.

The objective function setting unit may set a second objective function of the binary classifier by adding indicators indicating that the misclassification data is correctly predicted data within a predetermined range based on the misclassification rate of the data predicted by the binary classifier and the misclassification data of the binary classifier, and the parameter value determination unit may determine values of each of the second hyperparameters so that the second objective function value is minimized.

The objective function setting unit may set a third objective function of the probability inferring unit by adding, by the probability inferring unit, a difference between accuracy of the predicted data and a reference value of the accuracy for each of the predetermined number of durability probability sections and a predetermined multiple of a standard deviation between accuracies in the predetermined number of durability probability sections, and the parameter value determination unit may determine values of each of the third hyperparameters so that the third objective function value is minimized.

The durability evaluation system may further include a parameter optimization unit that samples nearby data based on the values of each of the hyperparameters, determines a surrogate indicating the sampled data, and updates interpolation and scaling of the values using the surrogate to optimize the values of the corresponding hyperparameters among the first to third hyperparameters.

According to still another aspect of the present disclosure, there is provided a computer-readable storage medium storing a computer program including a control instruction for performing the above-described durability evaluation method.

According to the present disclosure, it is possible to evaluate durability performance of a vehicle for each mesh indicating parts of the vehicle based on 3D data including stress analysis data when a plurality of external forces are applied to the vehicle, determine whether the durability performance of the vehicle meets predetermined criteria, and determine the durability performance of the vehicle with a probability distribution to generate data indicating locations of parts of the vehicle whose durability performance does not meet the predetermined criteria and the probability that the durability performance of each part of the vehicle belongs to the section of the predetermined criterion.

In addition, by dividing the probability that the durability performance belongs to the predetermined criterion section into a plurality of sections and outputting the probability, it is possible to reduce misclassification in the evaluation of the durability performance of the vehicle and the accuracy of understanding the durability performance may be improved.

According to the present disclosure, by selecting hyperparameters for models such as a data filter, a binary classifier, and a probability inferring unit, and setting an objective function of each model to consider class imbalance among the hyperparameters, it is possible to improve prediction performance of each model.

According to the present disclosure, by having the objective function to consider not only recall and precision of the data itself, but also durability performance of data near the misclassification data, and removing an outlier with low frequency of occurrence, it is possible to balance each class in data with severe class imbalance and make data in each of the plurality of classes clear.

According to the present disclosure, by considering the durability performance of data near the misclassification data, it is possible to secure accuracy of data predicted by each model to a certain level or greater.

According to the present disclosure, by using a surrogate to find an optimal solution to a parameter value, it is possible to find a global optimal solution rather than a local optimal solution, it is possible to improve a speed of searching for the optimal solution, and by implementing optimization in a non-convex function, it is possible to uniformly improve accuracy of each class.

### BRIEF DESCRIPTION OF THE DRAWINGS

FIG. 1 is a block diagram schematically illustrating a configuration of a durability evaluation system according to an embodiment.

FIG. 2 is an exemplary diagram for describing the relationship between each component of a control unit of FIG. 1 and data input and output to each component when the control unit performs learning.

FIG. 3 is a flowchart for describing a durability evaluation method according to an embodiment.

FIG. 4 is a detailed flowchart illustrating an operation of extracting feature data based on neighbor windows in S3 of FIG. 3.

FIG. 5 is a rendering image of parts of a vehicle in a three-dimensional (3D) space.

FIG. 6 is a detailed flowchart illustrating step S31 of FIG. 4.

FIG. 7 is an exemplary diagram for describing four points corresponding to vertices of one quadrangular mesh, in accordance with an example embodiment.

FIG. 8 is an exemplary diagram illustrating four combinations of triangles that may be generated from the quadrangular mesh of FIG. 7.

FIG. 9 is an exemplary diagram for describing four interior angles for each of the four combinations of triangles in FIG. 8.

FIG. 10 is an exemplary diagram for describing weighting for meshes belonging to the same neighbor windows.

FIG. 11 is a flowchart for describing a durability evaluation method according to an embodiment.

FIG. 12 is a block diagram schematically illustrating detailed components of a model tuner illustrated in FIG. 2.

FIG. 13 is an example of a confusion matrix.

FIG. 14 is a flowchart of a durability evaluation method for tuning a model parameter.

FIG. 15 is an exemplary diagram for describing a plurality of hyperparameters.

FIG. 16A is a diagram for describing an operation of a parameter optimization unit.

FIG. 16B is a diagram for describing an operation of a parameter optimization unit.

FIG. 16C is a diagram for describing an operation of a parameter optimization unit.

### DETAILED DESCRIPTION

Hereafter, embodiments of the present disclosure will be described in detail with reference to the accompanying drawings and the same or similar components are given the same reference numerals and are not repeatedly described. The suffix “module” and/or “unit” for components used in the following description is given or mixed in consideration of only the ease of writing of the specification, and therefore, does not have meanings or roles that distinguish from each other in themselves. Further, when it is decided that a detailed description for the known art related to the present disclosure may obscure the gist of the present disclosure, the detailed description will be omitted. Further, it should be understood that the accompanying drawings are provided only in order to allow exemplary embodiments of the present disclosure to be easily understood, and the spirit of the present disclosure is not limited by the accompanying drawings, but includes all the modifications, equivalents, and substitutions included in the spirit and the scope of the present disclosure.

Terms including an ordinal number such as first, second, etc., may be used to describe various components, but the components are not limited to these terms. The terms are used only to distinguish one component from another component.

It will be further understood that terms “include” or “have” used in the present specification specify the presence of features, numerals, steps, operations, components, parts mentioned in the present specification, or combinations thereof, but do not preclude the presence or addition of one or more other features, numerals, steps, operations, components, parts, or combinations thereof.

Among the components according to an embodiment, a program implemented as a set of instructions specifying a control algorithm necessary for controlling other components may be installed in a component that controls other components under specific control conditions. The control component may process input data and stored data according to installed programs to generate output data. The control component may include non-volatile memory for storing programs and memory for storing data.

A durability evaluation system according to an embodiment may evaluate durability performance of a vehicle based on stress analysis data for an object. Hereinafter, the object subject to the durability evaluation will be described as a vehicle. However, since it takes a lot of time to model a virtual vehicle, the durability performance of the vehicle is evaluated based on stress analysis data for the body, which is a skeleton of the vehicle. The stress analysis data may be acquired through stress analysis simulation. The stress analysis simulation is a simulation that extracts data for the stress that occurs at a plurality of points on the body when the virtual vehicle is under specific conditions in a virtual space. The stress analysis data may indicate stresses at all the points included in the body.

A Belgian road is a term of art, referring to a road used for durability testing for a vehicle. The virtual vehicle may be driven on a virtual Belgian road in a three-dimensional (3D) space. Driving the vehicle on the Belgian road may be viewed similarly to putting the vehicle in various situations. However, in order to extract valid life data, the virtual vehicle should be driven on the virtual Belgian road for a relatively long period of time. In an embodiment, the life data may be data that matches a plurality of 3D meshes that constitute the body. The life data matching each mesh indicates the durability performance of the mesh against the corresponding external force. The greater the value indicated by the stress analysis data, the lower the durability performance indicated by the life data. The durability performance can be expressed as a driving distance of the vehicle during which the corresponding mesh remains in a state in which it may perform its normal functions. For example, the durability performance indicated by the life data may indicate the driving distance of the vehicle in km.

In an embodiment, in order to generate life data of various vehicles, instead of driving various virtual vehicles as many as the number of vehicles on the virtual Belgian road, the stress analysis simulation is performed on each of the plurality of external forces to predict the life data from a plurality of stress analysis data using the plurality of acquired stress analysis data for the virtual vehicle and the life data matching the plurality of acquired stress analysis data. Hereinafter, for convenience of description, the virtual vehicle will be described as a vehicle.

According to an embodiment, durability performance of a vehicle may be evaluated according to a plurality of stress analysis data for a plurality of external forces. Here, the plurality of external forces includes various types of external forces that may be applied to a vehicle when the vehicle is driving on a Belgian road. For example, the plurality of external forces may include FR torsion, RR torsion, positive max moment, negative max moment, bending, bouncing, etc. The FR torsion may be an external force applied to the vehicle when a rear portion of the vehicle is fixed and a front portion of the vehicle is twisted. The RR torsion may be an external force applied to the vehicle when the front portion of the vehicle is fixed and the rear portion of the vehicle is twisted. The positive max moment may be an external force applied to the vehicle when vibration fatigue reaches its maximum in a direction toward the top when the vehicle shakes from side to side. The negative max moment may be an external force applied to the vehicle when the vibration fatigue reaches its maximum in a direction toward the bottom when the vehicle shakes from side to side. The bending may be an external force applied to the vehicle when the vehicle is fixed and a central portion of the vehicle is bent in a vertical direction. The bouncing may be an external force applied to the vehicle when the vehicle repeatedly bounces in a vertical direction.

Hereinafter, a durability evaluation system that evaluates durability performance of a vehicle based on a plurality of stress analysis data of the vehicle to which each of the plurality of external forces is applied will be described with reference to the drawings.

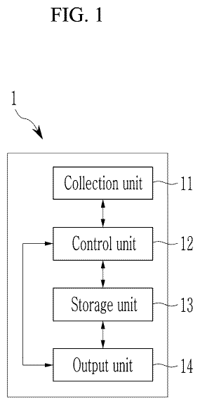

FIG. 1 is a block diagram schematically illustrating a configuration of a durability evaluation system according to an embodiment.

A durability evaluation system 1 may include a collection unit 11, a control unit 12, a storage unit 13, and an output unit 14.

The collection unit 11 may collect 3D data including stress analysis data for the body and transmit the collected 3D data to the control unit 12. The collection unit 11 may receive 3D data from an external device. Alternatively, the collection unit 11 may collect 3D data from a separate server or the like that generates stress analysis data and transmit the collected 3D data to the control unit 12.

The 3D data may include data defining a plurality of 3D meshes constituting a 3D body. For example, the 3D data includes data indicating shapes of each mesh, a plurality of stress analysis data acquired by performing a stress analysis simulation for each of the plurality of external forces in each mesh, and life data matching each mesh. Data indicating the shapes of each mesh may include location information of each vertex constituting each mesh, information on the connection relationship between the vertices, etc. The 3D data includes data indicating the shapes of the meshes for each of the plurality of meshes and a plurality of stress analysis data for each mesh, in which the life data may match each of the plurality of meshes.

Hereinafter, the mesh for describing an embodiment in this specification is assumed to be a 3D mesh.

For example, the 3D data may include the stress analysis data of each mesh when the FR torsion is applied to the vehicle, the stress analysis data of each mesh when the RR torsion is applied to the vehicle, the stress analysis data of each mesh when the positive max moment is applied to the vehicle, and the stress analysis data of each mesh when the negative max moment is applied to the vehicle.

Hereinafter, the 3D data may further include target data which is data that defines a plurality of meshes constituting a 3D body of a vehicle that is a subject of durability performance evaluation in a virtual space, virtual material data which is data that defines a plurality of meshes constituting a 3D body of a first virtual vehicle (hereinafter, a first virtual situation) in which the material of the vehicle is adjusted in the virtual space, and virtual thickness data which is data that defines a plurality of meshes constituting a 3D body of a second virtual vehicle (hereinafter, a second virtual situation) in which a thickness of the vehicle is adjusted in the virtual space. Each of the target data, virtual material data, and virtual thickness data includes data indicating the shapes of the meshes for each of the plurality of meshes and the plurality of stress analysis data for each mesh, and the corresponding life data may match each of the plurality of meshes.

The durability evaluation system 1 evaluates the durability performance of the vehicle based on the plurality of stress analysis data for each of the plurality of meshes constituting the body. The control unit 12 may learn a method of predicting life data indicating durability performance based on a plurality of stress analysis data, and extract meshes indicating durability performance less than a predetermined threshold value among the plurality of meshes according to the learned results. In addition, the control unit 12 may learn a method of predicting a probability that durability performance of each extracted mesh belongs to which section of a predetermined number of durability probability sections, and determine a probability that each mesh belongs to which section of a predetermined number of durability probability sections according to the learned results. Hereinafter, the predetermined threshold value may be determined in advance with initial information.

In order to apply 3D data for other vehicles to the learned control unit 12, the collection unit 11 may collect data indicating the shape of the mesh for each of multiple meshes for different vehicles and other data that includes the plurality of stress analysis data in each mesh and does not match the life data.

The control unit 12 may include a processor that controls the collection unit 11, the storage unit 13, and the output unit 14. The processor refers to a component that processes an arithmetic operation, a logical operation, a determination operation, etc., to provide at least one function, and may be implemented through hardware, software, or a combination of hardware and software. For example, the processor may be implemented by software such as tasks, classes, sub-routines, processes, objects, execution threads, or programs performed in a predetermined region on a memory or hardware such as a field-programmable gate array (FPGA) or an application-specific integrated circuit (ASIC) and may be implemented by a combination of the software and the hardware. The processor may be included in a computer readable storage medium or parts of the processor may be dispersed and distributed in a plurality of computers. The processor may be, for example, a central processing unit (CPU). The control unit 12 may execute other processes and programs included in the storage unit 13, and transmit and receive data from the storage unit 13 according to requests by the execution process. The control unit 12, which will be described later, and each operation of the detailed components of the control unit 12 may be performed by the processor.

The storage unit 13 may include a computer-readable storage medium storing a computer program that includes control instructions for evaluating the durability performance of the plurality of meshes constituting the body through the operation of the control unit 12, which will be described later. The storage unit 13 may include a storage device that stores a database. The storage unit 13 may match the life data to the plurality of meshes indicated by the plurality of stress analysis data among the 3D data collected from the collection unit 11 and store the life data in the database.

The output unit 14 may display data indicating the meshes extracted from the control unit 12 on a user interface. In addition, the output unit 14 may display the probability that the durability performance belongs to each of the predetermined number of durability probability sections determined by the control unit 12 on the user interface.

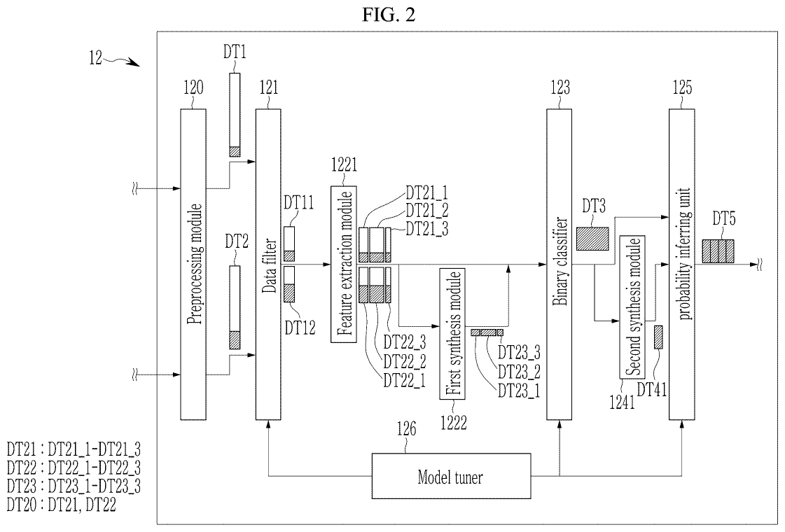

Hereinafter, the components of the control unit and the operation of each component will be described with reference to FIGS. 2 to 11.

FIG. 2 is an exemplary diagram for describing the relationship between each component of a control unit of FIG. 1 and data input and output to each component when the control unit performs learning.

Referring to FIG. 2, the control unit 12 may include a preprocessing module 120, a data filter 121, a first synthesis module 1222, a feature extraction module 1221, a binary classifier 123, and a second synthesis module 1241, a probability inferring unit 125, and a model tuner 126.

The preprocessing module 120 may transmit data obtained by preprocessing target data (hereinafter, raw data) DT1 among the 3D data collected by the collection unit 11 and data (hereinafter, virtual preprocessing data) DT2 obtained by preprocessing virtual material data and virtual thickness data to the data filter 121.

The data filter 121 may filter the raw data DT1 and output target filtering data DT11. The data filter 121 may filter virtual preprocessing data DT2 and output virtual filtering data DT12.

The feature extraction module 1221 may extract target feature data DT21 from the target filtering data DT11. The feature extraction module 1221 may extract virtual feature data DT22 from the virtual filtering data DT12.

Hereinafter, for convenience of description, the target feature data DT21 and the virtual feature data DT22 are referred to as feature data DT20.

The first synthesis module 1222 may generate first synthetic data DT23 indicating durability performance less than a predetermined threshold value based on the feature data DT20.

In addition, each of the feature data DT20 and the first synthetic data DT23 may include corresponding first feature data DT21_1, DT22_1, and DT23_1, second feature data DT21_2, DT22_2, and DT23_2, and third feature data DT21_3, DT22_3, and DT23_3.

The binary classifier 123 may determine first output data DT3 using the feature data DT20 and the first synthetic data DT23 as input.

The second synthesis module 1241 may generate second synthetic data DT41 based on the first output data DT3.

The probability inferring unit 125 may determine second output data DT5 using the first output data DT3 and the second synthetic data DT41 as input.

A hatched portion among the plurality of data DT1, DT2, DT11, DT12, DT2, DT3, DT41, and DT5 illustrated in FIG. 2 schematically illustrates the number of data that matches life data indicating durability performance less than a predetermined threshold value in each of the plurality of data.

Each of the plurality of data DT1, DT2, DT11, DT12, DT2, and DT41 excluding the first output data DT3 and the second output data DT5 may be a plurality of data with multiple dimensions. Each of the plurality of data DT1, DT2, DT11, DT12, DT2, and DT41, excluding the first output data DT3 and the second output data DT5 may be a dataset that has the number of rows determined based on the number of data, and the number of columns determined based on the number of dimensions. For example, data including n data in m dimensions may be a dataset having m columns and n rows.

The number of rows indicating the durability performance less than the predetermined threshold value among the life data in the virtual preprocessing data DT2 may be greater than the number of rows indicating the durability performance less than the predetermined threshold value among the life data in the raw data DT1.

In addition, the number of rows indicating the durability performance less than the predetermined threshold value among the life data in the virtual filtering data DT12 may be greater than the number of rows indicating the durability performance less than the predetermined threshold value among the life data in the target filtering data DT11.

Hereinafter, the operations of each component of the control unit 12 will be described with reference to the relationship between the plurality of data DT1, DT2, DT11, DT12, DT2, DT3, DT41, and DT5.

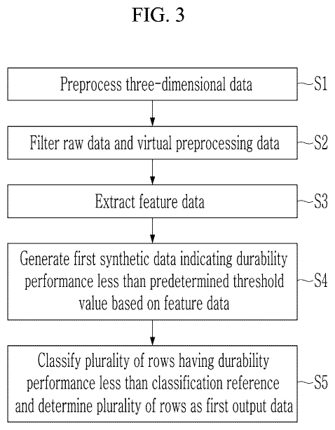

FIG. 3 is a flowchart for describing a durability evaluation method according to an embodiment.

The preprocessing module 120 may preprocess the 3D data (S1). Here, the preprocessing may include removing outliers in the stress analysis data from the 3D data, performing log transformation, and performing nonlinear scaling. The preprocessing module 120 may improve a dispersion of the 3D data and derive meaningful data through the preprocessing.

The preprocessing module 120 may transmit the raw data DT1 and the virtual preprocessing data DT2 obtained by preprocessing the target data, the virtual material data, and the virtual thickness data to the data filter 121.

Each of the raw data DT1 and the virtual preprocessing data DT2 may include a plurality of rows indicating each of the plurality of meshes. Each column of the plurality of rows may include values based on the plurality of stress analysis data and the data indicating the shape of the mesh, respectively, and the life data may be matched in each row. The number of columns in each of the raw data DT1 and the virtual preprocessing data DT2 corresponds to the number of external forces applied to the vehicle and the number of parameters indicating the shape of the mesh to extract the stress analysis data from the 3D data, and the number of rows may correspond to the number of meshes indicated by the 3D data. The parameters indicating the shape of the mesh may include factors related to the thickness, normal vector, curvature, etc., of the body. The life data may not be included in one of the plurality of columns constituting each row, but may be included in a separate data column matching each of the plurality of rows. For example, when the 3D data is 200,000 data in seven dimensions for six external forces and thickness, the raw data DT1 and the virtual preprocessing data DT2 each are a dataset including 200,000 rows in 7 columns. In this case, the same row in each of the raw data DT1 and the virtual preprocessing data DT2 includes six values based on six stress analysis data for one mesh, respectively, and each column includes one value based on the thickness.

In the raw data DT1, among the plurality of life data, the raw data matching the life data indicating the durability performance greater than or equal to the predetermined threshold value may correspond to a majority class, and the raw data matching the life data indicating the durability performance less than the predetermined threshold value may correspond to a minority class. The raw data DT1 may be hyper imbalanced data in which a difference between the number of majority classes and the number of minority classes is large. Therefore, in order to alleviate the degree of imbalance of the hyper imbalanced data, the preprocessing module 120 transmits not only the raw data DT1 but also the virtual preprocessing data DT2 to the data filter 121.

The data filter 121 may filter the raw data DT1 and the virtual preprocessing data DT2 (S2). The data filter 121 may partially resolve the hyper imbalance of the raw data DT1 and adjust the hyper imbalance of the raw data DT1 to the general level of imbalanced data.

The data filter 121 may determine criteria (hereinafter, filter criteria) for durability performance indicated by a plurality of life data matching a plurality of stress analysis data based on the raw data DT1 and the virtual preprocessing data DT2. The filter criteria may be a level required to minimize the possibility of errors occurring when the binary classifier classifies a mesh with durability performance less than a predetermined threshold value. Accordingly, the durability performance indicated by the filter criterion may be higher than the durability performance indicated by the predetermined threshold value.

The data filter 121 may be implemented based on a boosting algorithm such as RUSBoost and an ensemble model. The data filter 121 may determine the filter criteria for the durability performance through the boosting algorithm and the ensemble model based on the plurality of stress analysis data.

The data filter 121 may determine, as the target filtering data DT11, the plurality of rows indicating the durability performance less than the filter criteria in the raw data DT1. Each column of the plurality of rows may include values based on the plurality of stress analysis data and the data indicating the shape of the mesh, respectively, and the life data may be matched in each row. In addition, the data filter 121 may determine, as the virtual filtering data DT12, the plurality of rows indicating the durability performance less than the filter criteria in the virtual preprocessing data DT2. Each column of the plurality of rows may include values based on the plurality of stress analysis data and the data indicating the shape of the mesh, respectively, and the life data may be matched in each row.

Hereinafter, the plurality of meshes indicated by the target filtering data DT11 are referred to as an input mesh.

The number of dimensions of the target filtering data DT11 may correspond to the number of dimensions of the raw data DT1. In addition, the number of rows of the target filtering data DT11 may be smaller than the number of rows of the raw data DT1. The data filter 121 may reduce calculation costs of the feature extraction module 1221 by inputting the target filtering data DT11, which has fewer rows than the raw data DT1, to the feature extraction module 1221.

In addition, the number of dimensions of the virtual filtering data DT12 may correspond to the number of dimensions of the virtual preprocessing data DT2. In addition, the number of rows of the virtual filtering data DT12 may be smaller than the number of rows of the virtual preprocessing data DT2. The data filter 121 may reduce the calculation cost of the feature extraction module 1221 by inputting the virtual filtering data DT12, which has fewer rows than the virtual preprocessing data DT2, in the feature extraction module 1221.

For example, when the raw data DT1 is 200,000 data in seven dimensions, the target filtering data DT11 is a dataset including 120,000 data in seven dimensions, and when the virtual preprocessing data DT2 is 200,000 data in seven dimensions, the virtual filtering data DT12 may be a dataset including 120,000 data in seven dimensions.

The target filtering data DT11 and the virtual filtering data DT12 may be transmitted to the feature extraction module 1221.

The feature extraction module 1221 may extract the feature data DT3 based on each of the target filtering data DT11 and the virtual filtering data DT12 (S3).

The number of dimensions of the target feature data DT31 is greater than the number of dimensions of the target filtering data DT11, and the number of rows of the target feature data DT31 may correspond to the number of rows of the target filtering data DT11. The number of dimensions of the virtual feature data DT32 is greater than the number of dimensions of the virtual filtering data DT12, and the number of rows of the virtual feature data DT32 may correspond to the number of rows of the virtual filtering data DT12.

For example, when the target filtering data DT11 is a dataset including 120,000 data in seven dimensions and the virtual filtering data DT12 is a dataset including 120,000 data in seven dimensions, the target feature data DT31 is a dataset including 120,000 data in 28 dimensions, and the virtual feature data DT32 is a dataset including 120,000 data in 28 dimensions.

The feature extraction module 1221 may extract data indicating stress features, neighbor stress features, and shape features as the feature data DT2 from each of the target filtering data DT11 and the virtual filtering data DT12.

The target feature data DT21 may include first feature data DT21_1 indicating stress features based on the plurality of stress analysis data, second feature data DT21_2 indicating neighbor stress features based on the stress analysis data for each of a plurality of neighbor windows (NGB window), and third feature data DT21_3 indicating shape features based on the data indicating the shapes of each mesh.

Similarly, the virtual feature data DT22 may include first feature data DT22_1 indicating the stress features, second feature data DT22_2 indicating the neighbor stress features, and third feature data DT22_3 indicating the shape features.

The feature data DT20 may include the plurality of rows. The columns in each of the plurality of rows include a plurality of columns indicating corresponding values among the first feature data DT21_1 and DT22_1, a plurality of columns indicating corresponding values among the second feature data DT21_2 and DT22_2, and a plurality of columns indicating corresponding values among the third feature data DT21_3 and DT22_3.

Neighbor windows of a specific mesh may be a concept encompassing meshes (hereinafter, neighbor meshes) located within a predetermined range based on the specific mesh.

For example, like a first neighbor window located nearest to a specific mesh in a direction (hereinafter, outward direction) away from the specific mesh, a second neighbor window located nearest to the first neighbor window in the outward direction, a third neighbor window located at the second neighbor window in the outward direction, a plurality of neighbor windows located step by step are located.

First, the operation of the feature extraction module 1221 to extract the first feature data DT21_1 and DT22_1 will be described.

The feature extraction module 1221 may extract the first feature data DT21_1 from the value based on the stress analysis data in the target filtering data DT11. The feature extraction module 1221 may extract the first feature data DT22_1 from the value based on the stress analysis data in the virtual filtering data DT12.

For example, it is assumed that the value based on the stress analysis data in the target filtering data DT11 is 120,000 data in six dimensions, and the value based on the stress analysis data in the virtual filtering data DT12 is 120,000 data in six dimensions. The feature extraction module 1221 extracts 120,000 stress features in six dimensions as the first feature data DT21_1 and extracts 120,000 stress features in six dimensions as the first feature data DT22_1. Therefore, the first feature data DT21_1, DT22_1, and DT23_1 may be 120,000+120,000=240,000 data in six dimensions.

Hereinafter, the operation of the feature extraction module 1221 to extract the second feature data DT21_2 and DT22_2 will be described.

The feature extraction module 1221 may extract data indicating the shapes of each of the plurality of meshes from the target filtering data DT11. The feature extraction module 1221 may find a plurality of neighbor windows for each of the plurality of meshes, and extract values indicating stress analysis data with inverse distance weighting (IDW) applied to a plurality of neighbor meshes belonging to each of the plurality of neighbor windows as second feature data DT21_2. Hereinafter, the number of neighbor windows may be predetermined as initial information.

The feature extraction module 1221 may extract data indicating the shapes of each of the plurality of meshes from the virtual filtering data DT12. The feature extraction module 1221 may find a plurality of neighbor windows for each of the plurality of meshes, and extract values indicating stress analysis data with inverse distance weighting (IDW) applied to a plurality of neighbor meshes belonging to each of the plurality of neighbor windows as second feature data DT22_2.

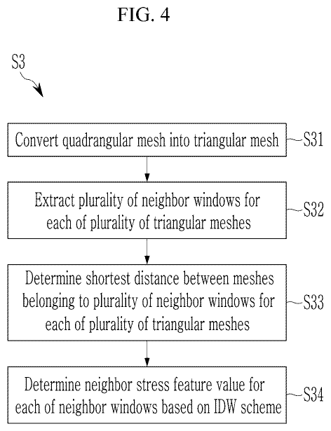

Hereinafter, the operation of the feature extraction module 1221 to extract the second feature data DT21_2 and DT22_2 based on the target filtering data DT11 and the virtual filtering data DT12 will be described with reference to FIGS. 4 to 10.

FIG. 4 is a detailed flowchart illustrating an operation of extracting feature data based on neighbor windows in S3 of FIG. 3.

The feature extraction module 1222 may transform a quadrangular mesh into a triangular mesh among the plurality of meshes indicated by the target filtering data DT11 and the plurality of meshes indicated by the virtual filtering data DT12 (S31). Each of the plurality of meshes indicated by the target filtering data DT11 and the plurality of meshes indicated by the virtual filtering data DT12 may be either the quadrangular mesh or the triangular mesh. In this case, for the quadrangular mesh, a surface of a mesh connecting each vertex of the mesh may not be a flat surface. Since the target filtering data DT11 and virtual filtering data DT12 are not in a 3D standard format, including the quadrangular mesh, in order to extract the second feature data DT21_2 and DT22_2 and third feature data DT21_3 and DT22_3, the feature extraction module 1222 may transform the target filtering data DT11 and the virtual filtering data DT12 into the 3D standard format. Each of the plurality of meshes indicated by the data in the 3D standard format may be a triangular mesh having three vertices.

In order to transform the target filtering data DT11 and the virtual filtering data DT12 into the 3D standard format, the feature extraction module 1222 requires the transformation from the quadrangular mesh into the triangular mesh among the plurality of meshes indicated by the target filtering data DT11 and the plurality of meshes indicated by the virtual filtering data DT12. Since it is difficult to numerically extract the feature data DT20 from data for the quadrangular mesh, the feature extraction module 1222 may transform the quadrangular mesh into the triangular mesh to transform the target filtering data DT11 and the virtual filtering data DT12 into the 3D standard format. The feature extraction module 1222 may extract the feature data DT20 from the target filtering data DT11 and the virtual filtering data DT12 in the 3D standard format. The process of transforming, by the feature extraction module 1222, the quadrangular mesh into the triangular mesh may be referred to as mesh triangulation. Hereinafter, the quadrangular mesh among the plurality of meshes indicated by the target filtering data DT11 and the quadrangular mesh among the plurality of meshes indicated by the virtual filtering data DT12 will be described as a plurality of quadrangular meshes.

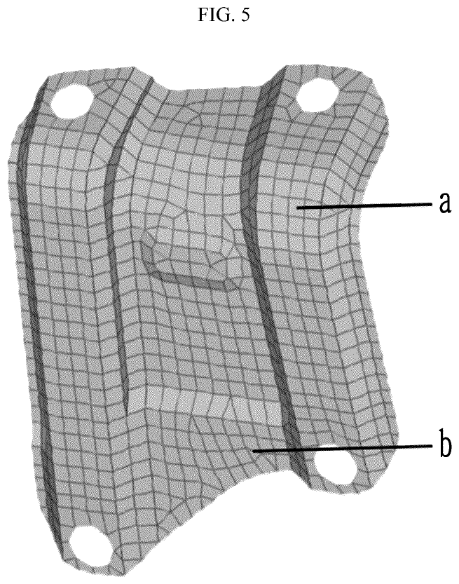

Examples of the quadrangular mesh and the triangular mesh will be described with reference to FIG. 5.

FIG. 5 is a rendering image of parts of a vehicle in a three-dimensional (3D) space.

As illustrated in FIG. 5, vehicle parts may be divided into a plurality of meshes.

Referring to FIG. 5, of the shapes of the meshes expressed in the 3D space, a part indicated by (a) is the quadrangular mesh, and a part indicated by (b) is the triangular mesh.

The target filtering data DT11 and the virtual filtering data DT12 may include data indicating the shape of each of the plurality of quadrangular meshes. The feature extraction module 1222 may transform each of the plurality of quadrangular meshes into two triangular meshes.

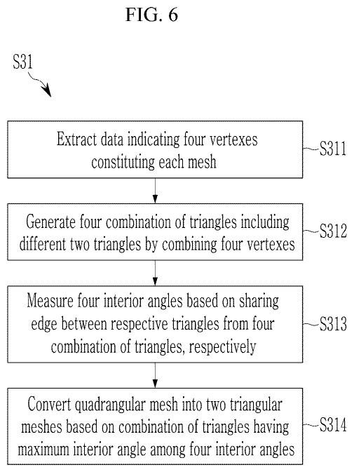

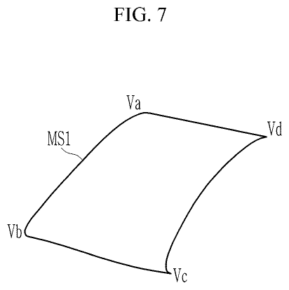

Hereinafter, the operation of the feature extraction module 1221 to transform one of the plurality of quadrangular meshes into the two triangular meshes in step S31 of FIG. 4 will be described as an example with reference to FIGS. 6 to 9. Each step in FIG. 6 is described with reference to exemplary diagrams of FIGS. 7 to 9.

FIG. 6 is a detailed flowchart illustrating step S31 of FIG. 4.

The feature extraction module 1222 may extract data indicating four vertices constituting the quadrangular mesh (S311).

FIG. 7 is an exemplary diagram for describing four points corresponding to vertices of one quadrangular mesh.

In the example of FIG. 7, the feature extraction module 1222 may extract data indicating four points Va, Vb, Vc, and Vd, which are each vertex of a quadrangular mesh MS1, from data indicating the shapes of each of the plurality of quadrangular meshes.

The feature extraction module 1222 may generate four combinations of triangles including two different triangles by combining four vertices (S312).

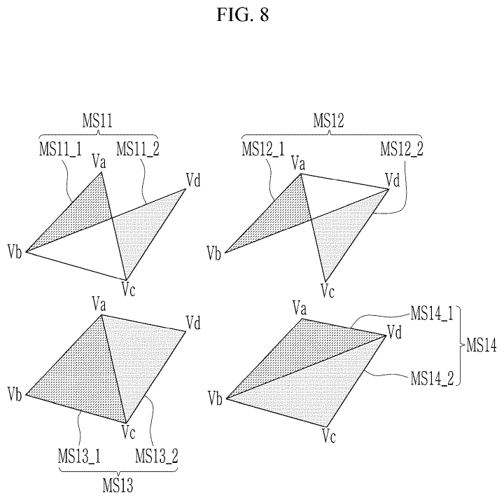

FIG. 8 is an exemplary diagram illustrating the four combinations of triangles that may be generated from the quadrangular mesh of FIG. 7.

In the example of FIG. 8, the feature extraction module 1222 may generate a combination MS11 of triangles including one triangle MS11_1 using points Va, Vb, and Vc of the four points Va, Vb, Vc, and Vd as vertices and another triangle MS11_2 using points Vb, Vc, and Vd as vertices.

In addition, the feature extraction module 1222 may generate a combination MS12 of triangles including one triangle MS12_1 using points Va, Vb, and Vd of the four points Va, Vb, Vc, and Vd as vertices and another triangle MS12_2 using points Va, Vc, and Vd as vertices.

In addition, the feature extraction module 1222 may generate a combination MS13 of triangles including one triangle MS13_1 using points Va, Vb, and Vc of the four points Va, Vb, Vc, and Vd as vertices and another triangle MS13_2 using points Va, Vc, and Vd as vertices.

In addition, the feature extraction module 1222 may generate a combination MS14 of triangles including one triangle MS14_1 using points Va, Vb, and Vd of the four points Va, Vb, Vc, and Vd as vertices and another triangle MS14_2 using points Vb, Vc, and Vd as vertices.

The feature extraction module 1222 may measure four interior angles based on sharing edges between respective triangles from each of the four combinations MS11, MS12, MS13, and MS14 of triangles (S313).

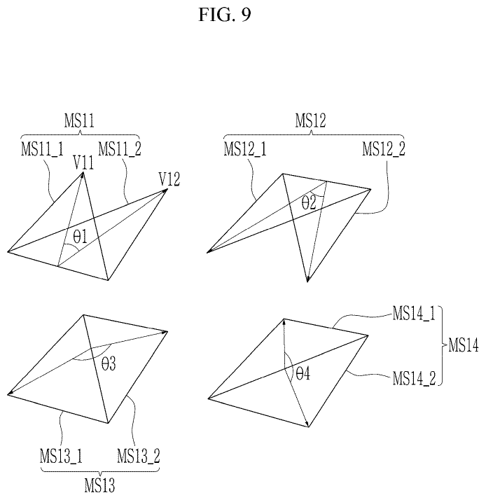

FIG. 9 is an exemplary diagram for describing four interior angles for each of the four combinations of triangles in FIG. 8.

In the example of FIG. 9, the feature extraction module 1222 may extract a sharing edge between one triangle MS11_1 and another triangle MS11_2 and points V11 and V12 not shared between the two triangles MS11_1 and MS11_2, in the combination MS11 of triangles. The feature extraction module 1222 may extract an interior angle θ1 between a midpoint vector pointing from a centroid of the sharing edge to one point V11 and a midpoint vector pointing from the centroid of the sharing edge to another point V12.

In this way, the feature extraction module 1222 may extract the remaining interior angles θ2 to θ4 from each of the remaining combinations MS12 to MS14 of triangles.

The feature extraction module 1222 may transform the quadrangular mesh into two triangular meshes based on the combination of triangles having a maximum interior angle among the four interior angles θ1 to θ4 (S314).

The feature extraction module 1222 may transform the quadrangular mesh into two triangular meshes based on the combination of triangles having the maximum interior angle. For example, the quadrangular mesh MS1 may be transformed into the two triangular meshes in the form of two triangles MS13_1 and VS13_2 based on the combination MS13 of triangles having the maximum interior angle θ3. The reason why the feature extraction module 1222 uses the interior angle of the combination of triangles as the criteria for transforming the quadrangular mesh into the two triangular meshes is that the shape of the combination of triangles having the maximum interior angle may be determined to be nearest to the shape of the quadrangular mesh before transformation.

Hereinafter, for convenience of description, it is assumed that the plurality of triangular meshes indicated by the target filtering data DT11 include the triangular mesh transformed through steps S311 to S314 from the existing triangular mesh and the plurality of quadrangular meshes, and the plurality of triangular meshes indicated by the virtual filtering data DT12 include the triangular mesh transformed from the existing triangular mesh and the plurality of quadrature meshes through steps S311 to S314.

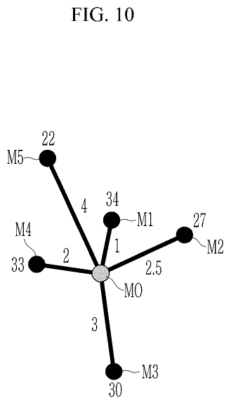

Hereinafter, the operation of extracting the second feature data DT21_2 and DT22_2 based on the plurality of triangular meshes indicated by the target filtering data DT11 and the virtual filtering data DT12, respectively, will be described with reference to FIGS. 4 and 10.

The feature extraction module 1222 may extract a plurality of neighbor windows for each of the plurality of triangular meshes indicated by the target filtering data DT11 and the virtual filtering data DT12 (S32).

A k-th neighbor window may be a concept encompassing a k-th neighbor mesh based on each of the plurality of triangular meshes indicated by the target filtering data DT11 and the first synthetic data DT21. Hereinafter, k is a natural number greater than or equal to 1, and may be determined in advance as initial information.

A first neighbor mesh for a specific mesh may be a plurality of triangular meshes that share at least one of the vertices and edges constituting the specific mesh, and if k>1, the k-th neighbor mesh for the specific mesh may be a plurality of triangular meshes excluding a k−1-th neighbor mesh among the meshes that share at least one of the vertices and edges constituting the k−1-th neighbor mesh.

For example, a second neighbor window ngb2 for one triangular mesh among the plurality of triangular meshes indicated by each of the target filtering data DT11 and the first synthetic data DT21 may include triangular meshes that share at least one of the vertices and edges constituting one triangular mesh. A third neighbor window ngb3 for one triangular mesh may include one of the triangular meshes that shares at least one of the vertices and edges constituting each of the triangular meshes belonging to the second neighbor window, and a plurality of triangular meshes that are not triangular meshes belonging to the second neighbor window.

Hereinafter, an operation of the feature extraction module 1222 to determine the shortest distance between the meshes based on the plurality of triangular meshes indicated by each of the target filtering data DT11 and the virtual filtering data DT12 and extract the neighbor stress features based on the shortest distance will be described.

The feature extraction module 1222 may determine the shortest distance between the plurality of triangular meshes indicated by each of the target filtering data DT11 and the virtual filtering data DT12 and meshes belonging to a plurality of neighbor windows for each triangular mesh (S33).

When determining the shortest distance between the meshes, the feature extraction module 1221 may determine the shortest distance using a Geodesic distance that indicates the distance along the surface because vibration has features transmitted along the surface. When calculating the distance between two vertices, unlike a Euclidean distance, which is a straight line distance between each vertex, the Geodesic distance may connect two vertices along the edge of the mesh, and thus, may be a distance that takes the surface into account.

The feature extraction module 1222 may determine neighbor stress feature values for each of the plurality of neighbor windows based on the IDW method (S34). The IDW is a method of interpolating an observed value for a reference point, and is an interpolation method of applying a smaller weight value to observed values at other points as a distance between the reference point and other points increases.

In an embodiment, a plurality of neighbor features are extracted from a first neighbor feature to a k-th neighbor feature for each of the plurality of external forces. The IDW method that applies a weighted average of the stress analysis data for each of the plurality of neighbor windows from the first neighbor window to the k-th neighbor window for each of the plurality of meshes indicated by the target filtering data DT11 and the plurality of meshes indicated by the first synthetic data DT21 to extract neighbor features is used.

Referring to [Equation 1] below, the k-th neighbor stress analysis data for one external force may be a value obtained by applying the weighted average of the IDW to each stress analysis data for one external force.

$${z}_{ngb} ( k ) = \frac{\sum ( {w}_{i} * {z}_{i} )}{\sum {w}_{i}} \qquad ( Equation 1 )$$

Here, z_{ngb}(k) is the k-th neighbor stress analysis data. k is a natural number greater than or equal to 2. wᵢ is weighting of an i-th mesh among the plurality of meshes belonging to the k-th neighbor window. wₛi is a natural number greater than or equal to 1. zᵢ is one stress analysis data of the i-th mesh among the plurality of meshes belonging to the k-th neighbor window. zᵢ

The weighting applied to each of the plurality of meshes belonging to the neighbor window may be inversely proportional to a square of the shortest distance based on the specific mesh that serves as a reference among the plurality of triangular meshes indicated by each of the target filtering data DT11 and the virtual filtering data DT12.

Even if the k-th neighbor meshes are the same based on the specific mesh, the distances from the specific mesh that serves as the reference may be different. Accordingly, a weighted average method may be applied in which weighting of stress analysis data for a mesh that is far from the specific mesh among the same k-th neighbor meshes is small, and the weighting of the stress analysis data for neighbor meshes is large.

Hereinafter, the operation of the feature extraction module 1222 to determine the neighbor stress analysis data for each neighbor window will be described with reference to FIG. 10.

FIG. 10 is an exemplary diagram for describing weight values for meshes belonging to the same neighbor windows.

Referring to FIG. 10, a mesh M0 corresponds to a central element that is a reference mesh, and five meshes M1 to M5 belong to the same neighbor window (e.g., third neighbor window). One stress analysis data for one external force matching each of the five meshes M1 to M5 is 34, 27, 30, 33, and 22 in order, and the distances of each of the five meshes M1 to M5 based on the mesh M0 to M5 is 1, 2.5, 3, 2, 4 in order.

In the example of FIG. 10, the neighbor stress analysis data of the third neighbor window may be determined to be 32.38 according to [Equation 2] below.

$${z}_{ngb} ( 3 ) = \frac{\frac{34}{{1}^{2}} + \frac{27}{{2.5}^{2}} + \frac{30}{{3}^{2}} + \frac{33}{{2}^{2}} + \frac{22}{{4}^{2}}}{\frac{1}{{1}^{2}} + \frac{1}{{2.5}^{2}} + \frac{1}{{3}^{2}} + \frac{1}{{2}^{2}} + \frac{1}{{4}^{2}}} = 32.38 \qquad ( Equation 2 )$$

Here, z_{ngb}(3) is the third neighbor stress analysis data for the mesh M0 which is the central element.

In this way, the feature extraction module 1221 may extract k neighbor stress features for a plurality of external forces as second feature data DT21_2 for each of the plurality of triangular meshes indicated by the target filtering data DT11. The feature extraction module 1221 may extract k neighbor stress features for a plurality of external forces as second feature data DT22_2 for each of the plurality of triangular meshes indicated by the virtual filtering data DT12.

Here, among the target filtering data DT11, through steps S311 to S314, two second feature data DT22_2 for each of the two triangular meshes may be extracted from each of the plurality of rows indicating the triangular mesh. In this case, data contained in one row may be transformed into two rows for each of the two triangular meshes.

For example, in 101-th and 102-th rows for one quadrangular mesh M indicated by the target filtering data DT11, the stress features for the quadrangular mesh M are included in the column corresponding to the first feature data DT21_1 in the same way. In the column corresponding to the second feature data DT21_2, neighbor stress features for one triangular mesh M1 of the two triangular meshes M1 and M2 based on the mesh M and neighbor stress features for the remaining one triangular mesh M2 of the two triangular meshes M1 and M2 are each included in each row. In the column corresponding to the third feature data DT21_3, shape features for one triangular mesh M1 and shape features for the remaining one triangular mesh M2 are each included in each row.

In one of the plurality of rows of the feature data DT20, p columns corresponding to the first feature data DT21_1 and DT22_1 may each include values indicating p stress features for each of p external forces, and p*k columns corresponding to the second feature data DT21_2 and DT22_2 may each include values indicating the first to k-th neighbor stress features for each of the p external forces.

For example, in one of the plurality of rows of the feature data DT20, values indicating stress features for a first external force, stress features for a second external force, stress features for a third external force, stress features for a fourth external force, stress features for a fifth external force, and stress features for a sixth external force may be included as first feature data in six columns, and in the same row, values indicating first neighbor stress features for each of the first to sixth external forces, second neighbor stress features for each of the first to sixth external forces, and third neighbor stress features for each of the first to sixth external forces may be included as second feature data in 6*3=18 columns may be included in 6*3=18 columns as second feature data.

Hereinafter, the operation of the feature extraction module 1221 to extract the third feature data DT21_3 and DT22_3 will be described.

The feature extraction module 1222 may extract data indicating the shapes of each of the plurality of meshes from each of the target filtering data DT11 and the virtual filtering data DT12. The feature extraction module 1222 may extract the shape features for each of the plurality of triangular meshes from the data indicating the shapes of each of the plurality of meshes.

The shape features include at least one of a thickness of a body corresponding to the mesh, a normal vector of a mesh, a curvature which is an angle between the normal vector of the mesh and a normal vector of a mesh and its neighbor mesh, and a width of a predetermined number of neighbor windows for the mesh. Here, the normal vector may be a vector that is a right angle to the surface of the mesh at a location of a specific point of the mesh and points outward from the object. The curvature may be a feature for considering the degree of vulnerability to external shock depending on the curvatures of each of the plurality of triangular meshes. The width of the predetermined number of neighbor windows may be a feature for considering the degree of vulnerability to the external shock depending on the location of the part indicated by the mesh among all parts in the body to which the mesh belongs. A width when the location of the part indicated by the specific mesh is a center of the body may be larger than an area when the location is a corner of the body. For example, based on a specific mesh, it is the sum of the widths of the areas occupied by the meshes belonging to three neighbor windows from the first neighbor window to the third neighbor window.

The dimensions of the third feature data DT21_3 and DT22_3 may be the same value as the number of shape features extracted by the feature extraction module 1221 corresponding to each row of the target filtering data DT11 and the virtual filtering data DT12.

For example, when four shape features including a thickness, a normal vector, a curvature, and a width of a predetermined number of neighbor windows are extracted as the third feature data DT21_3 and DT22_3, the third feature data DT21_3 and DT22_3 may be four-dimensional data.

The first feature data DT21_1 and DT22_1 may be n data of p dimensions, the second feature data DT21_2 and DT22_2 may be n data of p*k dimensions, the third feature data DT21_3 and DT22_3 may be n data in q dimensions, and the feature data DT20 may be n data in (p+p*k+q) dimensions.

In each of the plurality of rows of the feature data DT20, the classes may be labeled based on the life data matched in each row in the target filtering data DT11 and the virtual filtering data DT12 learned by the binary classifier 123. The class based on the life data may be a class indicating normal data in a row in which the durability performance indicated by the life data matched in each row is greater than or equal to the predetermined threshold value, and a class indicating abnormal data in a row in which the durability performance indicated by the life data is less than the predetermined threshold value.

The first synthesis module 1222 may generate first synthetic data DT23 indicating durability performance less than a predetermined threshold value based on the feature data DT20 (S4).

The feature data DT20 has a lower degree of imbalance than the raw data DT1, which is hyper imbalanced data, but is imbalance data in which there is a difference in the number of rows indicating the durability performance greater than or equal to the predetermined threshold value that is the majority class and the number of rows indicating the durability performance less than the predetermined threshold value that is the minority class. Accordingly, the first synthesis module 1222 may generate the first synthetic data DT23 corresponding to the minority class in order to resolve the imbalance.

The first synthesis module 1222 may be implemented in a synthetic minority oversampling technique (SMOTE) method to resolve the imbalance of the feature data DT20. The SMOTE method may utilize a K-nearest neighbor (KNN) algorithm. The first synthesis module 1222 may adjust a rate with the majority class by oversampling data corresponding to the minority class using the SMOTE method.

The first synthesis module 1222 may generate the first synthetic data DT23 according to the degree of imbalance of the feature data DT20 by comparing the number of majority classes and the number of minority classes. For example, when there are 100,000 normal data and 60,000 abnormal data in the feature data DT20, the first synthesis module 1222 generates 40,000 first synthetic data DT23 belonging to the abnormal data.

The first synthesis module 1222 may oversample the plurality of rows corresponding to the abnormal data among the feature data DT20 by using the plurality of rows as original data (hereinafter, first SMOTE original data).

The first synthetic data DT23 may include data generated by the first synthesis module 1222 using some rows corresponding to the target feature data DT21 among the first SMOTE original data as first original data (hereinafter, first SMOTE data) and data generated by the first synthesis module 1222 using some rows corresponding to the virtual feature data DT22 among the first SMOTE original data as second original data (hereinafter, second SMOTE data). The rate of the first SMOTE data and the second SMOTE data may be determined based on the rate of the number of rows included in the first original data and the number of rows included in the second original data among the first SMOTE original data. For example, when the rate of the first original data and the second original data is 1:3 and there are 40,000 SMOTE data to be generated, the first synthesis module 1222 generates 30,000 first SMOTE data from the first original data, and generates 10,000 second SMOTE from the second original data.

Since the first synthetic data DT23 is data synthesized based on the first SMOTE original data, the first synthetic data DT23 may have the number of dimensions corresponding to the number of dimensions of the first SMOTE original data. For example, when the first SMOTE original data is a dataset in 28 dimensions, the first synthetic data DT23 may also be a dataset in 28 dimensions. Accordingly, the first synthetic data DT23 may include the first feature data DT23_1 indicating the stress features, the second feature data DT23_2 indicating the neighbor stress features, and third feature data DT23_3 indicating the shape features.

The first synthetic data DT23 may include the plurality of rows corresponding to the abnormal data. The columns in each of the plurality of rows include a plurality of columns indicating corresponding values among the first feature data DT23_1, a plurality of columns indicating corresponding values among the second feature data DT23_2, and a plurality of columns indicating corresponding values among the third feature data DT23_3.

The life data does not match in each of the plurality of rows of the first synthetic data DT23. The first synthetic data DT23 is not generated from the 3D data itself as the original data. That is, since the first synthetic data DT23 originates from at least one of the first SMOTE original data, the first synthetic data DT23 does not correspond to each mesh. Since the life data is data that matches the mesh, the first synthetic data DT23 does not include the life data. However, since each of the plurality of rows of the first synthetic data DT23 is a row generated based on the first SMOTE original data corresponding to the abnormal data, a class indicating the abnormal data learned by the binary classifier 123 may be labeled. Although the first synthesis module 1222 is described as being implemented in the SMOTE method, the present disclosure is not limited thereto, and the first synthesis module 1222 may be implemented based on a boosting algorithm such as ADABoost. In addition, the first synthesis module 1222 may be included in the binary classifier 122.

The binary classifier 122 may classify the plurality of rows with the durability performance less than the predetermined classification criterion (hereinafter, classification criterion) by using the feature data DT20 and the first synthetic data DT23 in multiple dimensions as an input, and determine the plurality of rows as the first output data (S5). The classification criterion may be a level in multiple dimensions for the binary classifier to class each of the plurality of rows included in the feature data DT20 and the first synthetic data DT23 in multiple dimensions into a class indicating normal data with high durability performance or a class indicating abnormal data.

The binary classifier 122 may determine the classification criteria that predict matched life data as a target from a plurality of features included in a plurality of columns for each row in the feature data DT20 and the first synthetic data DT23 in multiple dimensions.

The binary classifier 122 may be implemented based on the ensemble model. For example, the binary classifier 122 may be implemented based on the boosting learning algorithm such as the ADABoost.

The binary classifier 122 may generate a plurality of classifiers and combine the classification criteria of each of the plurality of classifiers to ultimately derive final classification criteria. The binary classifier 122 may combine the plurality of classification criteria by assigning weight values to the classification criteria of each of the plurality of classifiers.

The binary classifier 122 may learn a method of determining classification criteria that predicts life data indicating durability performance based on a plurality of features included in a plurality of columns and labels of each row, in each of the plurality of rows of the feature data DT20 and the first synthetic data DT23. For example, the binary classifier 122 may perform a test that trains based on the feature data DT20 to which the life data matches in each row, and target the life data based on the first synthetic data DT23 to which the data is not matched.

The binary classifier 122 may classify each of the plurality of rows included in the target feature data DT21 into the class indicating the normal data or a class indicating the abnormal data according to the determined classification criteria.

The binary classifier 122 may determine the plurality of rows classified into the class indicating the abnormal data among the plurality of meshes constituting the body as first output data DT3.

When the binary classifier 122 classifies at least one of two rows for one quadrangular mesh among the plurality of meshes constituting the body into the class indicating the abnormal data, the binary classifier 122 may determine all the two rows for one quadrangular mesh as the first output data DT3.

In addition, the control unit 12 may operate the learned binary classifier 122 by applying 3D data to other vehicles. The control unit 12 may extract feature data based on other data and extract the first synthetic data based on the feature data. The learned binary classifier 122 may determine, as the first output data DT3, the data indicating the mesh corresponding to the row classified into the class indicating the abnormal data among the plurality of meshes for other vehicles based on the feature data and the first synthetic data.

The output unit 14 may display the information indicating the mesh indicated by each of the plurality of rows of the first output data DT3 on the user interface. For example, the output unit 14 may display the location of the mesh corresponding to the row classified into the class indicating the abnormal data among the virtual bodies displayed in the user interface in different colors.

The first output data DT3 may include the data indicating the location of the mesh indicated by each of the plurality of rows of the first output data DT3 among the plurality of meshes constituting the virtual body. The first output data DT3 may be used as an indicator to evaluate the durability performance of the vehicle.

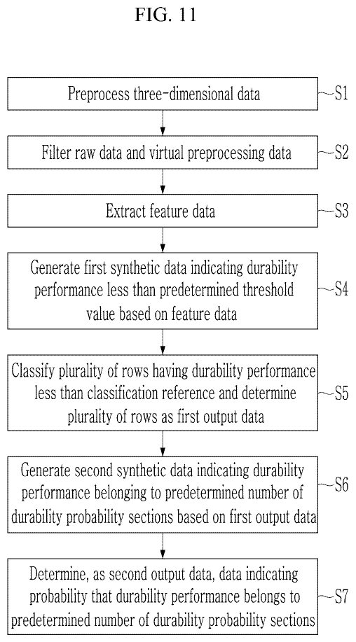

Hereinafter, the operation of the probability inferring unit 125 to infer the probability that the durability performance of the mesh indicated by each of the plurality of first output data DT3 belongs to each of the predetermined number of durability probability sections will be described with reference to FIG. 11.

FIG. 11 is a flowchart for describing a durability evaluation method according to an embodiment.

Steps S1 to S5 of FIG. 11 may operate in the same manner as steps S1 to S5 of FIG. 3, and description of overlapping parts thereof may be omitted.

The second synthesis module 1241 may generate second synthetic data DT41 indicating the durability performance belonging to the predetermined number of durability probability sections based on the first output data DT3 (S6). Here, the predetermined number of threshold values that serve as the basis for the predetermined number of durability probability sections may be determined in advance as initial information. For example, five durability probability sections may be determined in advance by four threshold values for the durability performance.

The plurality of rows of the first output data DT3 are the imbalanced data in which the number of rows belonging to each of the predetermined number of probability sections is different.

The second synthesis module 1241 may be implemented in the SMOTE method. The operation of the second synthesis module 1241 to perform oversampling based on the original data may be the same as the operation of the first synthesis module 1222 to perform oversampling based on the original data. Hereinafter, the original data of the second synthesis module 1241 is assumed to be data (hereinafter, second SMOTE original data) including the plurality of rows of the first output data DT3.

The second SMOTE original data may be divided into the predetermined number of classes, each belonging to the predetermined number of durability probability sections. Hereinafter, for convenience of description, the second SMOTE original data is divided into five classes including a first class, a second class, a third class, a fourth class, and a fifth class in descending order of the durability performance. Each of the plurality of rows in the second SMOTE original data may belong to one of five durability probability sections divided into five classes.

The second synthesis module 1241 may generate the second synthetic data DT41 based on five classes. Alternatively, the second synthesis module 1241 may generate the second synthetic data DT41 based on four classes excluding the fifth class which has the highest durability performance among five classes. Hereinafter, the description will be made assuming that the second synthetic data DT41 is generated based on four classes.

The second synthesis module 1241 may oversample the plurality of rows belonging to each minority class among the second SMOTE original data as the original data.

For example, the number of rows belonging to the second class may be the largest. In this case, the second class may be viewed as the majority class, and the first, third, and fourth classes may be viewed as the minority class. Accordingly, the second synthesis module 1241 may generate the second synthetic data DT41 corresponding to the minority class in order to resolve the imbalance.

The second synthesis module 1241 may generate the second synthetic data DT41 according to the degree of imbalance of the second SMOTE original data by comparing the number of majority classes and the number of minority classes. For example, when the number of rows belonging to each of the first to fourth classes in the second SMOTE original data is 1,000, 4,000, 3,000, and 2,000, the first synthesis module 1222 generates the second synthetic data DT41, which is a dataset of 6,000 data including 3,000 data belonging to the first class, 1,000 data belonging to the third class, and 2,000 data belonging to the fourth class based on the number (for example, 4,000) of majority classes.

Since the second synthetic data DT41 is data synthesized based on the second SMOTE original data, the second synthetic data DT41 may have the number of dimensions corresponding to the number of dimensions of the second SMOTE original data. For example, when the second SMOTE original data each are 28-dimensional dataset, similar to the feature data DT20, the second synthetic data DT41 may also include the first feature data indicating the stress features, the second feature data indicating the neighbor stress features, the third feature data indicating the shape features.

The second synthetic data DT41 may include the plurality of rows corresponding to the abnormal data, and each of the plurality of rows may belong to one of the predetermined number of classes.

The life data does not match in each of the plurality of rows of the second synthetic data DT41. The second synthetic data DT41 is not generated from the 3D data itself as the original data. That is, since the second synthetic data DT41 originates from at least one of the second SMOTE original data, the second synthetic data DT41 does not correspond to each mesh. Since the life data is the data that matches the mesh, the second synthetic data DT41 does not include the life data. However, in each of the plurality of rows of the second synthetic data DT41, the class indicating the abnormal data learned by the binary classifier 123 may be labeled, and at the same time, one of the predetermined number of classes learned by the probability inferring unit 125 may be labeled.

Although the second synthesis module 1241 is described as being implemented in the SMOTE method, the present disclosure is not limited thereto, and the second synthesis module 1241 may be implemented based on the boosting algorithm such as the ADABoost. In addition, the second synthesis module 1241 may be included in the probability inferring unit 125.

The probability inferring unit 125 may use the first output data DT3 and the second synthetic data DT41 as the input to determine, as the second output data DT5, the data indicating the probability that the durability performance of each of the plurality of meshes belongs to each of the predetermined number of durability probability sections (S7).

The probability inferring unit 125 may be implemented based on a radial basis function network (RBF Network).

The probability inferring unit 125 may perform membership inference to infer whether each of the plurality of rows in the first output data DT3 and the second synthetic data DT41 belongs to each of the predetermined number of durability probability sections. The probability inferring unit 125 may learn a method of predicting a probability that the durability performance belongs to a predetermined number of durability probability sections based on a label, which is one of a plurality of features included in a plurality of columns and a predetermined number of classes in each row, in each of the plurality of rows of the feature data DT20 and the second synthetic data DT41 for the membership inference.

The probability inferring unit 125 may include an input layer including an input vector indicating each row of the first output data DT3 and the second synthetic data DT41, and an output layer indicating the probability that the durability performance belongs to the predetermined number of durability probability sections. The probability inferring unit 125 may include the RBF layer whose activation function is a radial basis function between the input layer and the output layer. The probability inferring unit 125 may measure a similarity of the input layer for learning. A plurality of RBF neurons included in the RBF layer may each store one of examples of a dataset for training as a prototype. The output layer may be divided into a predetermined number of output categories indicating each of the predetermined number of classes. Each output category may indicate a weighted sum. The weighted sum may be a sum of values obtained by applying the weighting to each of the plurality of RBF neurons. The probability inferring unit 125 may determine the weighting of the RBF layer by learning a method of optimizing the output layer into a layout that may represent the predetermined number of durability probability sections. The probability inferring unit 125 may represent a membership value corresponding to each class as a probability.

The probability inferring unit 125 may determine, as the second output data DT5, the data indicating the membership value inferred as the probability that the durability performance of each of the plurality of meshes corresponding to the plurality of rows of the first output data DT3 belongs to each of the predetermined number of durability probability sections. In this case, the second output data DT5 may be data for the 3D body of the vehicle that is the subject of the durability performance evaluation.

The second output data DT5 may be data obtained by allowing the probability inferring unit 125 to add a value indicating the probability that each of the predetermined number of durability probability sections belongs to the plurality of rows of the first output data DT3 to a separate column.

For example, the probability inferring unit 125 may infer the probability that the durability performance indicated by each of the plurality of rows belongs to the first class, the probability that the durability performance belongs to the second class, the probability that the durability performance belongs to the third class, the probability that the durability performance belongs to the fourth class, and the probability that the durability performance belongs to the fifth class, respectively. In this case, the second output data DT5 may be data in which five columns indicating the probability that the durability performance belongs to the first to fifth classes are added to each of the plurality of rows.

In addition, the control unit 12 may operate the learned probability inferring unit 125 by applying the 3D data to other vehicles. The control unit 12 may extract the feature data based on other data and extract the second synthetic data based on the feature data. The learned probability inferring unit 125 may determine, as the second output data DT5, data indicating the probability that each mesh corresponding to the row classified into the class indicating the abnormal data by the binary classifier 123 among the plurality of meshes for other vehicles belongs to which section of the predetermined number of durability probability sections.

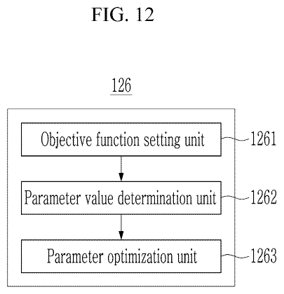

FIG. 12 is a block diagram schematically illustrating detailed components of a model tuner illustrated in FIG. 2.

Referring to FIG. 12, the model tuner 126 may include an objective function setting unit 1261, a parameter value determination unit 1262, and a parameter optimization unit 1263.

Hereinafter, for convenience of description, the life data matching each mesh will be referred to as “actual durability performance”, and the life data predicted by each of the data filter 121, the binary classifier 123, and the probability inferring unit 125 will be referred to as “predicted durability performance”. A mesh whose the actual or predicted durability performance is greater than or equal to the predetermined threshold value is assumed to be data with good durability performance, and a mesh whose the actual or predicted durability performance is less than the predetermined threshold value is assumed to be data with poor durability performance.

In addition, the durability performance indicated by the target filtering data DT11 and the virtual filtering data DT12 is assumed to be the durability performance predicted by the data filter 121. The durability performance indicated by the first output data DT3 is assumed to be the durability performance predicted by the binary classifier 123. The durability performance indicated by the second output data DT5 is assumed to be the data predicted by the probability inferring unit 125.

The model tuner 126 may compare the durability performance predicted by each of the data filter 121, the binary classifier 123, and the probability inferring unit 125 with the actual the durability performance to define the objective functions of each of the data filter 121, the binary classifier 123, and the probability inferring unit 125. The model tuner 126 may optimize hyperparameters of each of the data filter 121, the binary classifier 123, and the probability inferring unit 125 based on each objective function. Through this, the model tuner 126 may allow each class to equally improve the classification performance while minimizing the misclassification indicators of each of the data filter 121, binary classifier 123, and probability inferring unit 125.

The misclassification indicator is the summed value of False-Positive (G2B) data and False-Negative (B2G) data in a confusion matrix to measure the prediction performance of each of the data filter 121, binary classifier 123, and probability inferring unit 125. Here, it may be shown that the False-Positive (G2B) data is good actual durability performance, but is poor predicted durability performance, and the False-Negative data is actual poor durability performance, but is predicted good durability performance.

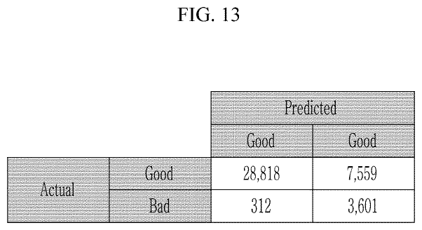

FIG. 13 is an example of the confusion matrix.

Referring to FIG. 13, the number of False-Positive (G2B) data in one of the data filter 121, the binary classifier 123, and the probability inferring unit 125 may be 7,559, and the number of False-Negative (B2G) data may be 312.

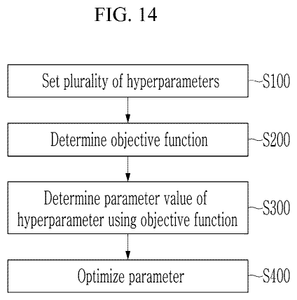

FIG. 14 is a flowchart of a durability evaluation method for tuning a model parameter.

Each operation in the flowchart illustrated in FIG. 14 may be performed in addition to the operations in the flowchart illustrated in FIG. 3 or FIG. 11, respectively.

Hereinafter, the detailed configuration and operation of each model tuner 126 will be described with reference to FIGS. 12 and 14.

The objective function setting unit 1261 may set hyperparameters corresponding to each of the data filter 121, the binary classifier 123, and the probability inferring unit 125 (S100).

The objective function setting unit 1261 may set a plurality of hyperparameters corresponding to the data filter 121, the binary classifier 123, and the probability inferring unit 125 among several parameters indicating the data filter 121, the binary classifier 123, and the probability inferring unit 125. The hyperparameters may be parameters whose corresponding values may be adjusted for modeling each of the data filter 121, the binary classifier 123, and the probability inferring unit 125.

A user may set the values corresponding to the plurality of hyperparameters, but in an embodiment, the model tuner 126 may automatically determine the values corresponding to the plurality of hyperparameters according to the predetermined criteria.

Cascade models according to an embodiment may be implemented with the data filter 121, the binary classifier 123, and the probability inferring unit 125, and the hyperparameters to be optimized in each of the data filter 121, the binary classifier 123, and the probability inferring unit 125 may be different, but the plurality of hyperparameters may be largely divided into a model hyperparameter, a class balancing parameter, and a data cleansing parameter.

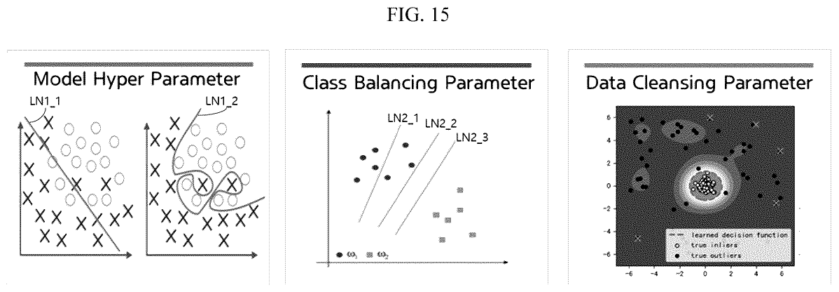

FIG. 15 is an exemplary diagram for describing a plurality of hyperparameters.

Referring to FIG. 15, the model hyperparameter may optimize complexity of a decision bound that divides each of the plurality of classes. As illustrated in FIG. 15, the model hyperparameter may include a plurality of hyperparameters that may optimize complexity of a boundary line to change a boundary line that divides the class represented by “O” and the class represented by “X” from a line LN1_1 to a line LN1_2.

Referring to FIG. 15, the class balancing parameter may optimize the imbalance of each of the plurality of classes according to the importance of each of the plurality of classes. As illustrated in FIG. 15, the class balancing parameter may include a plurality of hyperparameters capable of optimizing the imbalance for each class by comparing the importance between a class represented by “w1” and a class represented by “w2” and selecting one of a plurality of lines such as a line LN2_1, line LN2_2, a line LN2_3, etc., for the boundary line that divides the class represented by “w1” and the class represented by “w2” depending on the degree of importance boosting according to the comparison results.

Referring to FIG. 15, the data cleansing parameter may remove a distribution with a weak appearance frequency based on the data appearance probability of each of the plurality of classes and clarify data of each of the plurality of classes. As illustrated in FIG. 15, the data cleansing parameter may include the plurality of hyperparameters that may clarify a data area by dividing between inliers and outliers of “true” data through the learned decision function and removing some data among the true outliers with low frequency of occurrence.

The model tuner 126 may improve the performance of the data filter 121, the binary classifier 123, and the probability inferring unit 125 through an objective function that may additionally optimize not only the model hyperparameter but also the class balancing parameters and the data cleansing parameters.

The plurality of hyperparameters may include a hyperparameter corresponding to the data filter 121, a hyperparameter corresponding to the binary classifier 123, and a hyperparameter corresponding to the probability inferring unit 125. That is, the hyperparameter corresponding to the data filter 121, the hyperparameter corresponding to the binary classifier 123, and the hyperparameter corresponding to the probability inferring unit 125 may each be divided into the model hyperparameter, the class balancing parameter, and the data cleansing parameter. Hereinafter, the plurality of hyperparameters are assumed to include the hyperparameters corresponding to each of the data filter 121, the binary classifier 123, and the probability inferring unit 125.

Referring back to FIG. 14, the objective function setting unit 1261 may determine the objective function for determining the values of the hyperparameters corresponding to each of the data filter 121, the binary classifier 123, and the probability inferring unit 125 (S200). The objective functions of each of the data filter 121, the binary classifier 123, and the probability inferring unit 125 determined by the objective function setting unit 1261 may be an objective function that assigns weighting to the class balancing parameter and the data cleansing parameter among the model hyperparameter, the class balancing parameter, and the data cleansing parameter. When the number of data corresponding to each of the plurality of classes is imbalanced more than the class balancing parameter or the data cleansing parameter, the model hyperparameter may include fewer elements for adjusting the imbalance, fewer elements for removing outliers in data, or fewer elements for adjusting weighting for each of the plurality of classes. Therefore, the objective function setting unit 1261 may clarify the data area by setting the objective function that additionally considers not only the model hyperparameter but also the class balancing parameter and the data cleansing parameter and by balancing the durability performance data with severe class imbalance and removing the data with low frequency of occurrence among the plurality of classes.

In addition, the parameter value determination unit 1262 may use each objective function to determine parameter values of hyperparameters corresponding to each of the data filter 121, the binary classifier 123, and the probability inferring unit 125 (S300).

The parameter value determination unit 1262 may determine parameter values of hyperparameters corresponding to each of the data filter 121, the binary classifier 123, and the probability inferring unit 125 that minimize each objective function value.

Hereinafter, using Equations 3 to 8, the operation of the objective function setting unit 1261 to set the objective functions of each of the data filter 121, the binary classifier 123, and the probability inferring unit 125 and the operation of the parameter value determination unit 1262 to determine the parameter values will be described.

The objective function setting unit 1261 may set a first objective function corresponding to the data filter 121.

The first objective function may be a sum of the False-Negative (B2G) rate and a value obtained by applying a coefficient P1 for adjusting class imbalance to the False-Positive (G2B) rate, as in [Equation 3] below.

$$f 1 = ρ * \frac{G 2 {B}^{2}}{Good number} + \frac{B 2 {G}^{2}}{Bad number} \qquad ( Equation 3 )$$

Here, f1 is the first objective function corresponding to the data filter 121, ρ1 is the imbalance adjustment coefficient, good number is the number of data indicating that the actual durability performance is good durability among all the data predicted by the data filter 121, G2B is the number of False-Positive (G2B) data among all the data predicted by the data filter 121, bad number is the number of data indicating that the actual durability performance is poor among all the data predicted by the data filter 121, and B2G is the number of False-Negative (B2G) data among all the data predicted by the data filter 121.

The imbalance adjustment coefficient ρ₁ may be a value determined in advance by initial information. The balance adjustment coefficient value ρ₁ may be smaller as the rate of the bad number to the good number among all the data is smaller. The parameter value determination unit 1262 may determine the values of hyperparameters corresponding to the data filter 121 among the plurality of hyperparameters so that the value of the first objective function f1 is small.

The parameter value determination unit 1262 may use the imbalance adjustment coefficient ρ₁ value to lower the misclassification rate of the data filtered by the data filter 121, and determine the plurality of hyperparameters that causes the value of the first objective function f1 to be small, thereby improving the performance of the data filter 121.

The objective function setting unit 1261 may set a second objective function corresponding to the binary classifier 123.

Similar to [Equation 4] below, the second objective function may sum indicators indicating that the misclassification data is correctly predicted data within a predetermined range based on the misclassification rate and the misclassification data of the binary classifier 123.

$$f 2 = \frac{G 2 B + B 2 G}{2} + ( 1 - {ρ}_{2} ) * {index}_{G 2 B} + {ρ}_{2} * {index}_{B 2 G} \qquad ( Equation 4 )$$

Here, f2 is the second objective function corresponding to the binary classifier 123, ρ2 is the weighting of the False-Negative corresponding to the False-Positive, G2B is the number of False-Positive (G2B) data among all the data predicted by the binary classifier 123, and B2G is the number of False-Negative (B2G) data among all the data predicted by the binary classifier 123.

indexG2B may be a measure indicating the degree to which each False-Positive (G2B) data is close to the closest mesh among meshes with actual poor durability performance. indexB2G may be a measure indicating the degree to which each False-Negative (B2G) data is far from the closest mesh, excluding itself, among the meshes with actual poor durability performance.

indexG2B may be a smaller value the closer the False-Positive (G2B) data is to the actual bad durability data, and indexB2G may be a smaller value the farther the False-Negative (B2G) data is from the actual bad durability data.

The objective function setting unit 1261 may use the indexG2B value to reflect the extent to which the False-Positive (G2B) data itself is misclassified, but is predicted to match the actual durability performance in a predetermined area based on the data in the second objective function f2. In addition, the objective function setting unit 1261 may use the indexG2B value to reflect the extent to which the False-Negative (G2B) data itself is misclassified, but is predicted to match the actual durability performance in a predetermined area based on the data in the second objective function f2.

For example, the smaller the indexG2B value, the worse the durability, and thus, there is a portion where the actual durability performance is poor near incorrectly predicted False-Positive (G2B) data, which indicates that the prediction of the corresponding False-Positive (G2B) data is accuracy above a certain level. In addition, the smaller the indexB2G value, the better the durability, and thus, there is a portion where the actual durability performance is good near incorrectly predicted False-Negative (B2G) data, which indicates that the prediction of the corresponding False-Negative (B2G) data indicates accuracy above a certain level.

For example, indexG2B may be expressed as [Equation 5] below.

$${index}_{G 2 B} = {\sum }_{i} dist ( G 2 {B}_{i} , {bad}_{i} ) \qquad ( Equation 5 )$$

Here, G2Bᵢ may indicate a centroid of a mesh indicated by i-th data among the plurality of False-Positive (G2B) data, and badi may indicate the centroid of the mesh with the nearest distance from G2Bi among meshes with actual poor durability performance. dist may indicate a straight distance between G2Bi and badi.

However, indexG2B is not limited to [Equation 5] above, and the objective function setting unit 1261 may determine the indexG2B formula that causes the False-Positive (G2B) data to have a smaller indexG2B value as the distance from the closest mesh among the meshes with actual poor durability performance becomes shorter.

In addition, indexG2B may be expressed as [Equation 6] below.

$${index}_{B 2 G} = {\sum }_{j} {dist}^{- 1} ( B 2 {G}_{j} , {bad}_{j} ) \qquad ( Equation 6 )$$

Here, B2Gⱼ may indicate a centroid of a mesh indicated by j-th data among the plurality of False-Negative (B2G) data, and badⱼ may indicate the centroid of the mesh with the nearest distance from B2Gⱼ, excluding the mesh indicated by B2Gⱼ among meshes with actual poor durability performance. dist⁻¹ may indicate a reciprocal of the straight distance between B2Gⱼ and badj.

However, indexB2G is not limited to [Equation 6] above, and the objective function setting unit 1261 may determine a formula corresponding to indexB2G that causes the indexB2G value to be smaller as the distance from the closest mesh excluding itself among meshes with actual poor durability performance increases.

The weighting ρ2 may be a value determined in advance as the initial information. The weighting ρ2 value may be a real number exceeding 0 and less than 1. The parameter value determination unit 1262 may determine the values of hyperparameters corresponding to the binary classifier 123 among the plurality of hyperparameters so that the value of the second objective function f2 is small.

The parameter value determination unit 1262 may use the weighting ρ2 value to lower the misclassification rate of the data classified and output by the binary classifier 123, and determine the plurality of hyperparameter values that causes the value of the second objective function f2 to be small, thereby improving the performance of the binary classifier 123.

The objective function setting unit 1261 may set a third objective function corresponding to the probability inferring unit 125.

The third objective function may be the sum of the difference between the accuracy of each of the plurality of durability probability sections and the reference value and a predetermined multiple of the standard deviation of the accuracy of each of the plurality of durability probability sections, as in [Equation 7] below. Here, the accuracy may indicate the probability that the durability probability section to which the actual durability performance belongs and the durability probability section to which the predicted durability performance belongs are the same among all the predicted the durability performance data.

Hereinafter, the description will be made assuming that the number of plurality of durability probability sections is four.

$$f 3 = \vert Ref ( 1 ) - diagC ( 1 ) \vert + \vert Ref ( 2 ) - diagC ( 2 ) \vert + \vert Ref ( 3 ) - diagC ( 3 ) \vert + \vert Ref ( 4 ) - diagC ( 4 ) \vert + std ( diagC ( 1 : 4 ) ) * n \qquad ( Equation 7 )$$

Here, f3 is the third objective function corresponding to the probability inferring unit 125, Ref(k) is a reference value of a k-th class among the plurality of durability probability sections, diagC(k) is accuracy of the k-th class among the plurality of durability probability sections, std is the standard deviation, and n is a predetermined multiple. The predetermined multiple n may be a value determined in advance as the initial information.

Here, k may be a natural number greater than or equal to 1 and less than or equal to the number of durability probability sections. The durability performance of the k-th class among the plurality of durability probability sections may be low in the order that k is 1, 2, 3, and 4. For example, the first class among the plurality of durability probability sections may indicate data with the durability performance lower than the second class.

In addition, the accuracy of the k-th class may indicate the probability that the durability performance predicted by the probability inferring unit 125 among data whose actual durability performance belongs to the k-th class also belongs to the k-th class.

For example, diagC 1 may indicate the probability that the class predicted by the probability inferring unit 125 belongs to the first class among data whose actual durability performance belongs to the first class.

Ref 1, Ref 2, Ref 3, and Ref 4 may each be a value in advance as the initial information. Ref 1, Ref 2, Ref 3, and Ref 4 may each indicate a target value of accuracy in each class. For example, when the first class is predicted with accuracy of 90%, the second and third classes are predicted with accuracy of 100%, and the fourth class is predicted with accuracy of 70%, Ref 1 may be 90% and, Ref 2 and Ref 3 may each be 100%, Ref 4 may be 70%, and n may be 2.

In the above example, the third objective function f3 may be expressed as [Equation 8] below.

$$f 3 = \vert Ref ( 1 ) - diagC ( 1 ) \vert + \vert Ref ( 2 ) + Ref ( 3 ) - diagC ( 2 : 3 ) \vert + \vert Ref ( 4 ) - diagC ( 4 ) \vert + std ( diagC ( 1 : 4 ) ) * 2 \qquad ( Equation 8 )$$

Here, diagC 2:3 is a value obtained by summing the accuracy in the second class and the accuracy in the third class, and diagC 1:4 is a value obtained by summing the accuracy in each of the first to fourth classes.

The parameter value determination unit 1262 may determine the values of hyperparameters corresponding to the probability inferring unit 125 among the plurality of hyperparameters so that the value of the third objective function f1 is small.

The parameter value determination unit 1262 may use a reference value Ref(k) and multiple n values to determine a plurality of hyperparameter values that cause a misclassification of parts with low durability performance to be further reduced while uniformly increasing the accuracy in each of the plurality of durability probability sections predicted by the probability inferring unit 125, thereby improving the performance of the probability inferring unit 125.

Referring back to FIG. 14, the parameter optimization unit 1263 may adjust the parameter values of the hyperparameters corresponding to each of the data filter 121, the binary classifier 123, and the probability inferring unit 125 determined in step S300 and optimize the parameter values (S400).

The parameter optimization unit 1263 may optimize the parameter values of hyperparameters using surrogate optimization. The surrogate optimization may be an optimization method using a surrogate.

Conventionally, simulation models such as grid search, random search, and Bayesian search are each used to search for parameter solutions, and determine the optimal parameter values according to the searched results.

In an embodiment, the parameter optimization unit 1263 may tune the parameters values of hyperparameters to search for a global minimum solution through the surrogate method in which various simulation models such as the grid search, the random search, and the Bayesian search are combined, improve a search speed, and overcome a non-convex problem.

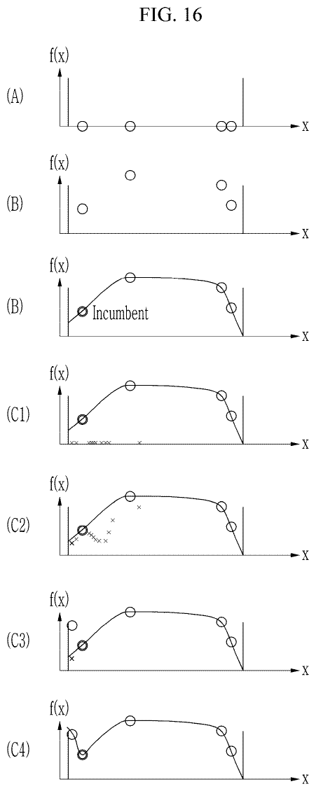

FIGS. 16A to 16C are diagrams for describing an operation of a parameter optimization unit.

Referring to FIGS. 16A to 16C, the parameter optimization unit 1263 may determine quasirandom points among the parameter values of each hyperparameter within bounds, and evaluate the objective function in each of the determined quasirandom points.

Referring to FIG. 16C, the parameter optimization unit 1263 may interpolate the hyperparameter value according to the objective function to generate the surrogate.

The operations illustrated in FIGS. 16C1 to C4 may be an operation included in the operations illustrated in FIG. 16C.

Referring to FIG. 16C1, in order to interpolate the hyperparameter value, the parameter optimization unit 1263 may sample nearby data based on one (e.g., incumbent data) of the hyperparameter values.

Referring to FIG. 16C2, the parameter optimization unit 1263 may determine a merit function indicating the sampled data. Here, the merit function may be a surrogate.

Referring to FIG. 16C3, the parameter optimization unit 1263 may evaluate the objective function value at the optimal point using the merit function.

Referring to FIG. 16C4, the parameter optimization unit 1263 may find optimal solutions for each of the plurality of hyperparameters by updating the interpolation and magnification of the parameter values.

The parameter optimization unit 1263 may repeatedly perform the operations illustrated in FIGS. 16C1 to C4, respectively. The parameter optimization unit 1263 may repeatedly perform an operation of sampling nearby data based on one hyperparameter value for values for each of the plurality of hyperparameters, determining the merit function indicating the sampled data, and updating the interpolation and magnification using the merit function, thereby finding the optimal solutions for the parameter values.

Hereinafter, Comparative Example will be described assuming that it is a system that performs the same operation as the durability evaluation system 1 according to an embodiment, except for the parameter optimization unit 1263.

In the comparative example, when the number of hyperparameters for each of the data filter corresponding to the data filter 121, the binary classifier corresponding to the binary classifier 123, and the probability inferring unit corresponding to the probability inferring unit 125 are each 3, 2 and 5, and the optimal solution is found by the Grid search method by dividing the candidate group into 10, an optimal solution for 10\hat{ }(3+2+5) parameters is searched. Compared thereto, the parameter optimization unit 1263 according to an embodiment can search for the optimal solution for parameters within 300 iterations and within 2 hours, thereby improving the speed compared to Comparative Example.

Hereinafter, the performance of the durability evaluation system 1 including the parameter optimization unit 1263 according to Comparative Example and an embodiment will be compared and described.

In the accuracy comparison, the accuracy of the data filter in Comparative Example was found to be 0.939, and the accuracy of the data filter 121 according to an embodiment was found to be 0.956. In terms of good accuracy where both the actual durability performance and the predicted durability performance are good durability, the good accuracy of the data filter in Comparative Example was found to be 0.939, and the good accuracy of the data filter 121 according to an embodiment was found to be 0.956. In terms of bad accuracy where both the actual durability performance and the predicted durability performance are bad durability, the bad accuracy of the data filter in Comparative Example was found to be 0.861, and the bad accuracy of the data filter 121 according to an embodiment was found to be 0.948.

In addition, in the accuracy comparison, the accuracy of the binary classifier in Comparative Example was found to be 0.804, and the accuracy of the binary classifier 123 according to an embodiment was found to be 0.883. In the good accuracy, the good accuracy of the binary classifier in Comparative Example was found to be 0.752, and the good accuracy of the binary classifier 123 according to an embodiment was found to be 0.885. In the bad accuracy, the bad accuracy of the binary classifier in Comparative Example was found to be 0.702, and the bad accuracy of the binary classifier 123 according to an embodiment was found to be 0.874.

In addition, according to an embodiment, the probability that there is poor durability data in the first adjacent mesh located closest to the mesh misclassified as poor durability is found to be 0.963, which may be determined to be a significantly high level. Therefore, according to an embodiment, the durability evaluation may be performed on each of the plurality of meshes, taking into account the durability performance of not only each of the plurality of meshes itself but also neighbor meshes.

As described above, the data filter 121, the binary classifier 123, and the probability inferring unit 125 optimized by the model tuner 126 may each output the corresponding data among the target filtering data DT11, the virtual filtering data DT12, the first output data DT3, and the second output data DT5.

The output unit 14 may display the information indicating the second output data DT5 on the user interface. For example, the output unit 14 may display the probability as a graph on the user interface.

The binary classifier 122 binary-classifies the durability performance of the plurality of meshes constituting the body into data with the value greater than or equal to or less than the classification criteria according to the predetermined classification criteria.

In addition, since the probability inferring unit 125 indicates the durability performance of the plurality of meshes constituting the body as the probability, the probability inferring unit has the advantage of being able to reduce the misclassification compared to evaluating the durability performance of the mesh through only the binary classifier 122 and provide highly accurate direction in determining the durability performance of the vehicle.

Although the embodiments of the present disclosure have been described in detail above, the scope of the present disclosure is not limited thereto, and various modifications and improvements by those of ordinary skill in the field to which the present disclosure pertains belong to the scope of the present disclosure.

What is claimed is:

1. A durability evaluation method performed by a processor, comprising:
filtering, by a data filter, a first data set for each of a plurality of meshes constituting a body of a target vehicle and a second data set for each of a plurality of meshes constituting a body of a virtual vehicle with an adjusted material or thickness of the target vehicle to output data indicating durability performance that is less than a predetermined filter criterion;
extracting feature data from the data indicating the durability performance that is less than the predetermined filter criterion, generating first synthetic data in which the durability performance is less than a predetermined threshold value, and determining data for a mesh indicating durability performance less than a predetermined threshold value among the plurality of meshes as first output data from the feature data and the first synthetic data through a binary classifier;
generating second synthetic data indicating durability performance belonging to a predetermined number of durability probability sections based on the first output data, and determining, by a probability inferring unit, data indicating a probability that the durability performance belongs to each of the predetermined number of durability probability sections from the first output data and the second synthetic data as second output data; and
determining a plurality of hyperparameter values constituting each of the data filter, the binary classifier, and the probability inferring unit so that a misclassification rate of each of the data filter, the binary classifier, and the probability inferring unit is reduced.

2. The durability evaluation method of claim 1, wherein:
the determining of the plurality of hyperparameter values includes:
setting first hyperparameters corresponding to the data filter, second hyperparameters corresponding to the binary classifier, and third hyperparameters corresponding to each of the probability inferring units;
setting objective functions of each of the data filter, the binary classifier, and the probability inferring unit to determine values of the first to third hyperparameters; and
determining values of corresponding hyperparameters among the first to third hyperparameters so that the objective function value is minimized.

3. The durability evaluation method of claim 2, wherein:
the setting of the objective functions of each of the data filter, the binary classifier, and the probability inferring unit includes
setting a first objective function of the data filter by adding a value obtained by multiplying a False-Positive rate of data predicted by the data filter by a predetermined adjustment coefficient and a False-Negative rate, and
the determining of the values of the corresponding hyperparameters among the first to third hyperparameters includes
determining values of each of the first hyperparameters so that the first objective function value is minimized.

4. The durability evaluation method of claim 2, wherein:
the setting of the objective functions of each of the data filter, the binary classifier, and the probability inferring unit includes
setting a second objective function of the binary classifier by adding indicators indicating that the misclassification data is correctly predicted data within a predetermined range based on the misclassification rate of the data predicted by the binary classifier and the misclassification data of the binary classifier, and
the determining of the values of the corresponding hyperparameters among the first to third hyperparameters includes
determining values of each of the second hyperparameters so that the second objective function value is minimized.

5. The durability evaluation method of claim 2, wherein:
the setting of the objective functions of each of the data filter, the binary classifier, and the probability inferring unit includes
setting a third objective function of the probability inferring unit by adding, by the probability inferring unit, a difference between accuracy of the predicted data and a reference value of the accuracy for each of the predetermined number of durability probability sections and a predetermined multiple of a standard deviation between accuracies in the predetermined number of durability probability sections, and
the determining of the values of the corresponding hyperparameters among the first to third hyperparameters includes
determining values of each of the third hyperparameters so that the third objective function value is minimized.

6. The durability evaluation method of claim 2, further comprising:
sampling nearby data based on the values of each of the hyperparameters;
determining a surrogate indicating the sampled data; and
optimizing the values of the corresponding hyperparameters among the first to third hyperparameters by updating interpolation and scaling of the value using the surrogate.

7. A durability evaluation system, comprising:
a collection unit that collects, by a data filter, a first data set for each of a plurality of meshes constituting a body of a target vehicle and second data set for each of a plurality of meshes constituting a body of a virtual vehicle with an adjusted material or thickness of the target vehicle; and
a processor that outputs data indicating a probability that durability performance belongs to each of a predetermined number of durability probability sections from the first data set and the second data set,
wherein the processor includes:
the data filter that outputs filter data indicating durability performance that is less than a predetermined filter criterion from the first data set and the second data set;
a binary classifier that determines, as first output data, data for a mesh indicating the durability performance less than a predetermined threshold value among the plurality of meshes from feature data extracted from the filter data and first synthetic data in which the durability performance synthesized from the feature data is less than the predetermined threshold value;
a probability inferring unit that determines, as second output data, data indicating a probability that durability performance belongs to each of the predetermined number of durability probability sections from the first output data and second synthetic data indicating the durability performance belonging to the predetermined number of durability probability sections synthesized based on the first output data; and
a model tuner that determines a plurality of hyperparameter values constituting each of the data filter, the binary classifier, and the probability inferring unit so that a misclassification rate of each of the data filter, the binary classifier, and the probability inferring unit is reduced.

8. The durability evaluation system of claim 7, wherein:
the model tuner includes:
an objective function setting unit that sets first hyperparameters corresponding to the data filter, second hyperparameters corresponding to the binary classifier, and third hyperparameters corresponding to each of the probability inferring units and sets objective functions of each of the data filter, the binary classifier, and the probability inferring unit for determining values of the first to third hyperparameters; and
a parameter value determination unit that determines values of corresponding hyperparameters among the first to third hyperparameters so that the objective function value is minimized.

9. The durability evaluation system of claim 8, wherein:
the objective function setting unit
sets a first objective function of the data filter by adding a value obtained by multiplying a False-Positive rate of data predicted by the data filter by a predetermined adjustment coefficient and a False-Negative rate, and
the parameter value determination unit
determines values of each of the first hyperparameters so that the first objective function value is minimized.

10. The durability evaluation system of claim 8, wherein:
the objective function setting unit
sets a second objective function of the binary classifier by adding indicators indicating that the misclassification data is correctly predicted data within a predetermined range based on the misclassification rate of the data predicted by the binary classifier and the misclassification data of the binary classifier, and
the parameter value determination unit
determines values of each of the second hyperparameters so that the second objective function value is minimized.

11. The durability evaluation system of claim 8, wherein:
the objective function setting unit
sets a third objective function of the probability inferring unit by adding, by the probability inferring unit, a difference between accuracy of the predicted data and a reference value of the accuracy for each of the predetermined number of durability probability sections and a predetermined multiple of a standard deviation between accuracies in the predetermined number of durability probability sections, and
the parameter value determination unit
determines values of each of the third hyperparameters so that the third objective function value is minimized.

12. The durability evaluation system of claim 8, further comprising:
a parameter optimization unit that samples nearby data based on the values of each of the hyperparameters, determines a surrogate indicating the sampled data, and updates interpolation and scaling of the values using the surrogate to optimize the values of the corresponding hyperparameters among the first to third hyperparameters.

13. A computer-readable storage medium storing a computer program including a control instruction for performing the durability evaluation method of claim 1.
